(19) United States
(12) Patent Application Publication
(10) Pub. No.: US 2005/0263899 A1
(43) Pub. Date: Dec. 1, 2005

(54) Photoresist process to enable sloped passivation bondpad openings for ease of metal step coverings

(76) Inventors: Swaminathan Sivakumar, Portland, OR (US); Curtis W. Ward, Hillsboro, OR (US); Timothy L. Hehr, Portland, OR (US); Mark A. Fradkin, Portland, OR (US)

Correspondence Address: INTEL/BLAKELY, 12400 WILSHIRE BOULEVARD, SEVENTH FLOOR, LOS ANGELES, CA, 90025-1030, US

(21) Appl. No.: 11/202,462

(22) Filed: Aug. 11, 2005

Related U.S. Application Data
(62) Division of application No. 10/750,200, filed on Dec. 30, 2003.

(51) Int. Cl. H01L 23/04

(52) U.S. Cl. 257/758

(57) ABSTRACT

The present invention relates to exposing a bond pad on a substrate. A bond pad is formed over a silicon substrate with the subsequent formation of a dielectric over the bond pad. A patterned resist is formed, and at least opening is processed to form a sloped sidewall profile. The sloped sidewall profile is subsequently etched and transferred to the dielectric layer, exposing the bond pad.

This is a Divisional application of Ser. No. 10/750,200 filed Dec. 30, 2003, which is presently pending.

### FIELD

The present invention relates to the field of manufacturing of integrated circuits and more specifically to using sloped sidewalls in resist and dielectric layer openings to improve the deposition quality of conductors or interconnections.

### BACKGROUND

The continued shrinking of integrated circuit switching devices has resulted in the geometries of electrically conductive interconnects also being reduced, as well as the reduction of bonding pad passivation openings, causing problems with step coverage of subsequent metalization deposition.

Current passivation processes create steep sidewalls. This can cause step coverage issues for subsequent metalization steps. Step coverage problems can occur due to the directional nature of the deposition process, resulting in a shadowing effect or a Damascene-type application of metals or conductors to the bond pad area. One solution is to control the heating during the metalization process which results in surface diffusion. Another solution is to rotate the substrate during metalization will reduce the shadowing effect. These two approaches to solving the step coverage problem results in improvements, but still does not produce a continuously uniform film.

FIG. 1A illustrates a typical prior art formation of a dielectric material 112 covering a bond pad 110. In FIG. 1A, a bond pad 110, and dielectric material 112 have been previously formed on a substrate. A conventional photo-resist mask 114 is shown formed over the dielectric layer 112 with a mask opening 120 exposing the area of the dielectric layer that covers the bond pad. The photo-resist mask 114 and dielectric material will be etched and processed. FIG. 1B shows the structure of FIG. 1A after etching of the dielectric layer 112 has been completed. The bond pad 110 is exposed, creating a trench 121, that may be used to subsequently form a compound or metal interconnect feature that will be connected to the bond pad 110, creating an electrically conductive path to the bond pad.

When one or more conductive compounds or metals are formed, the steeply sloped sidewall geometry of the band pad opening 121 causes a non-uniform or discontinuous deposition profile. As illustrated in FIGS. 1C and 1D, the bond pad opening may be inadequately filled. The normally steep sidewall geometry results in metalization voids, or thin profiles in certain areas that may result in non-conductive or highly resistive interconnections. FIG. 1C illustrates poor step coverage 132 due to a directional process and shadowing, resulting in a non-uniform conductive compound formation. The shadowing effect is shown by the broken path or gap 133 between conductive layer 131 and conductive layer 132. FIG. 1D illustrates the result of using an improved process of rotating the substrate during the formation of a conductor in the bond pad opening 143. However, the formation of the conductive layer is still unsatisfactory as step coverage 143 is still poor with respect to the non-uniformity of the conductive layer that is formed on the surface of the dielectric layer above the bond pad opening 140. The thin conductor areas 143 cause breaks or highly resistive conductive paths to the bond pad.

### BRIEF DESCRIPTION OF THE DRAWINGS

FIG. 1A illustrates a cross sectional view of a resist profile formed above a dielectric layer, bond pad and substrate.

FIG. 1B illustrates a cross sectional view of a bond pad opening profile that has been formed by a subsequent etch process from the substrate illustrated in FIG. 1A.

FIG. 1C illustrates a cross sectional view of the bond pad opening shown in FIG. 1B after a subsequent metalization or deposition process.

FIG. 1D illustrates a cross sectional view of the bond pad opening shown in FIG. 1B after a subsequent metalization or deposition process that includes rotation of the wafer to minimize the step problems shown in FIG. 1C.

FIG. 2A illustrates a cross sectional view of a resist layer mask exposure.

FIG. 2B illustrates a cross sectional view of a patterned resist profile formed above a substrate dielectric layer and bond pad.

FIG. 2C illustrates a cross sectional view of a bond pad opening profile that has been formed by a subsequent wet etch process performed to undercut the resist opening from the substrate illustrated in FIG. 2B.

FIG. 3A illustrates a cross sectional view of a resist profile formed above a substrate dielectric layer and bond pad.

FIG. 3B illustrates a cross sectional view of a sloped resist profile formed above a dielectric layer and bond pad of a substrate.

FIG. 3C illustrates a cross sectional view of the structure in FIG. 3B during an etch process where the resist material and dielectric layer are being removed by an etchant, and the sloped sidewall profile of the resist opening is approximately transferred to the dielectric layer.

FIG. 3D illustrates a cross sectional view of the substrate in FIG. 3B after being subjected to a subsequent etch process.

FIG. 3E illustrates a cross sectional views of the substrate in FIG. 3C after a subsequent metalization or conductive deposition process has been completed.

FIG. 4 is an SEM photograph of the sloped resist profile produced by the preferred embodiment of the invention.

### DETAILED DESCRIPTION

Described is a method that forms a sloped sidewall profile in a bond pad opening that will facilitate and improve the uniformity of a conductive layer that is deposited over and within the bond pad opening. The sloped sidewall used in conjunction with a metalization or conductor deposition process results in a continuous and uniform thickness. By using a sloped sidewall angle opening over the bond pad, a shadowing or Damascene effect during a metalization or deposition process is reduced or eliminated.

First, a bond pad is formed on a silicon substrate followed by the formation of a dielectric layer over the bond pad and the silicon substrate. The dielectric material formed over the bond pad is normally a non-conductive material such as a nitride, an oxide, or an oxy-nitride. The dielectric layer may be composed of a single or multiple layers of dielectric materials. The typical thickness of the dielectric layer may be up to several microns (um).

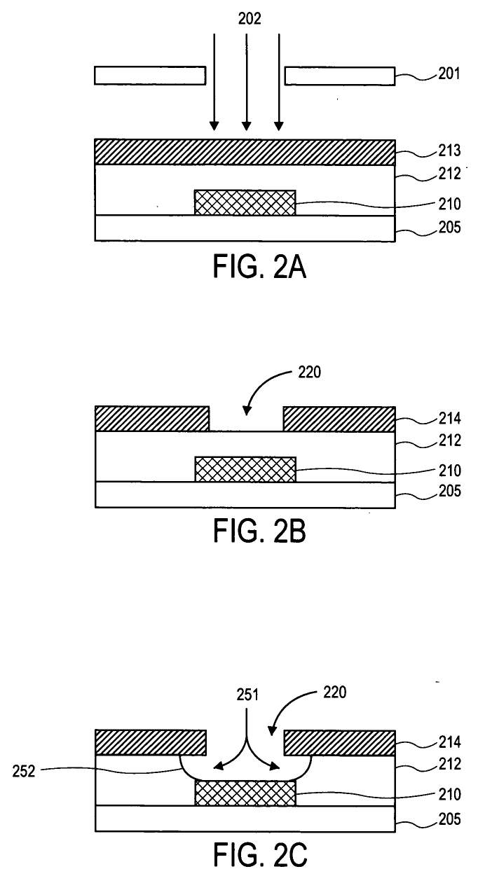

In one embodiment, as show in FIG. 2A, an underlying substrate 205 contains formed switching devices, with a bond pad 210 and inter-level dielectric layer 212 formed above the substrate. After a photoresist layer 213, is formed or spun above the substrate containing the bond pad and dielectric layer, the resist mask 201 is aligned, the photoresist layer is exposed 202, and developed.

In FIG. 2B, the excess unwanted photoresist is washed away to remove any unwanted resist or contaminants, forming a patterned resist layer with one or more openings 214. One or more openings in the patterned photoresist 220, are located approximately over the dielectric material 212 that covers the bond pad 210. To prepare the resist layer, a soft-baking step may be used to remove solvents, harden the photoresist material or to improve adhesion to the underlying substrate or dielectric material. The soft-bake process involves heating the wafer and photoresist below the resist material's glass transition temperature (Tg), typically at 90 to 120 degrees Celsius, for 2 to 30 minutes. The resist opening exposes dielectric material that is to be removed during a subsequent etch process.

A curved and sloped sidewall in the dielectric material opening to the bond pad may be formed using a straight sidewall profile in the resist mask, followed by using an isotropic etch process that undercuts the photoresist opening. This method will produce a curved sidewall in the dielectric layer over the bond pad opening. FIG. 2C illustrates an isotropic etch processes that yields a curved sidewall profile. A bond pad 210, dielectric material 212, and photoresist layer 214 with an opening over the bond pad 220, is subjected to an isotropic etch process 251. However, although somewhat of a sloped sidewall profile 252 is formed, the size of the post-etch dielectric opening is generally increased, and the depth or selectivity may be difficult to control in comparison to the patterned resist opening. Also, it is difficult to control the uniformity of the sidewall angle, profile, and bond pad exposure area.

In one embodiment of the invention, a sloped sidewall is formed in a photoresist opening by heating the patterned resist to or beyond the photoresist glass transition temperature (Tg). The photoresist material will reflow, and the sidewall angle of the photoresist opening may be controlled to vary the sidewall angle of the photoresist opening. The resist opening sloped sidewall is used to subsequently expose and form a sloped opening to a bond pad. A sloping sidewall may be formed over any dielectric or dielectric substitute that may benefit from having a sloping sidewall angle.

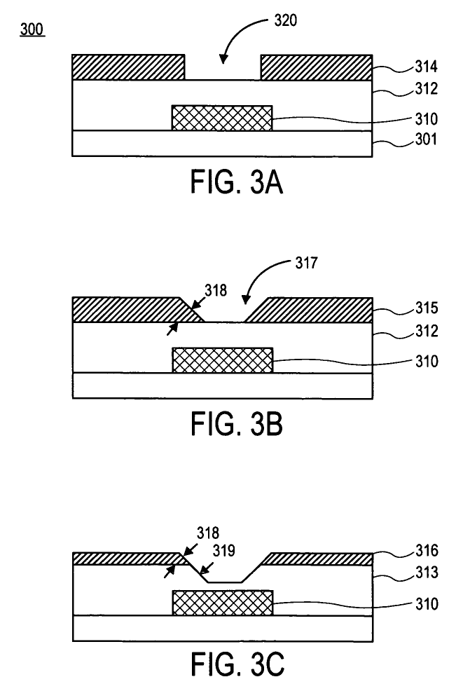

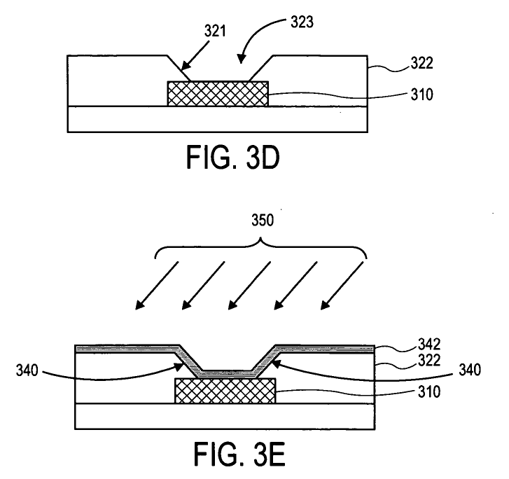

FIG. 3A illustrates the beginning structure 300. A substrate 301, containing the bond pad 310, is covered by a dielectric material 312 and a patterned photoresist layer 314. The patterned resist layer contains an opening above the bond pad 320. The underlying substrate may contain a plurality of switching devices such as an MOS transistor, or partially formed devices.

A variety of standard resist materials may be used, such as an I-Line resist, however, the invention is applicable to any chemically amplified (CAR) or non-chemically amplified resist material, such as I-line, g-line, ArF, EUV, or resists sensitive to 248 nm, 193 nm, or 157 nm light sources. Typical 193 nm resists include acrlyate, methacrylate and other hybrids. Also, the geometry size does not particularly matter, and it is possible to implement the process using 248 nm geometries or smaller.

In FIG. 3B, the patterned photoresist 315, is heated to or above the glass reflow temperature to obtain a sloped sidewall profile 318 in opening 317. The patterned resist may be heated by a variety of procedures including heating by direct contact with the wafer or substrate, by using a heated gas or gasses, or by irradiation. As shown in FIG. 3B, after heating the patterned resist, the resulting resist mask opening 317 is wider at the upper portion of the resist opening in comparison to the lower portion at the junction of the resist layer and dielectric layer. A preferred angle 318, is generally between 30 and 60 degrees.

In one embodiment, the patterned resist is heated by heating the underlying substrate from the non-photoresist side of the wafer. Heat is transferred through the wafer/substrate and begins heating the photoresist mask from the substrate side of the photoresist layer. The patterned photoresist layer that is in contact with the underlying substrate reaches or exceeds the glass transition temperature and begins to reflow. In this embodiment, an I-Line resist material, sensitive to 365 nm, is used and heated to 165 degrees Centigrade for 60 seconds. However, in other embodiments, the method works with other resist material such as I-line and ArF, other resists that are also sensitive to 248 nm or 193 nm, and materials sensitive to other light sources.

The temperature of the reflow step is dependant on the glass transition temperature (Tg) of the material, but typical processing conditions are 160 to 180 degrees Centigrade for 60 to 90 seconds on a proximity bake hot plate. This range would be also be relevant for other I-line, ArF, chemically amplified resists (CAR), and DUV (deep ultra-violet) resists. Generally, using temperatures that are higher over the chosen material's Tg will result in sidewalls that are more sloped or have a shallower angle. General ranges that will enable sloped sidewalls in resist openings are 140 C to 175 degrees Centigrade and time ranges of 50 to 90 seconds.

In general, the I-line and ArF resists have higher glass transition temperatures (Tg) than other 248 nm sensitive resists and would use the higher end of the temperature range described above. Other resist materials with sensitivities in the 248 nm or 193 nm wavelengths could also be used, with the temperature and time parameters depending on the glass transition temperature (Tg) of the resist polymer.

Also, there is a trade off between time and temperature. A process that uses higher temperatures for shorter time periods (e.g. 190 C for 15 sec) may produce similar results as 165 C for 60 seconds. Alternate temperature ranges for the reflow step may be necessary when using other classes of resist materials, but can be characterized and also used to create sloped resist openings. Further variations in the resist material, and temperature profile may also vary the slope angle of the photoresist sidewall profile, depending on the specific resist material and heating method that is used.

The substrate or wafer may also be heated by a variety of procedures including direct contact, heated gas, or irradiation. Another embodiment to achieve a sloped sidewall in a photoresist opening is implemented by heating the wafer from the resist side of the substrate. In this embodiment, the resist layer will form rounded corners on the top portion of the resist layer. The softening of the resist surface will propagate through the resist opening and form a sloped sidewall profile. Again, further variations in the resist material, temperatures, time, and temperature rise may vary the slope angle of the photoresist sidewall profile, depending on the specific resist material that is used in the process.

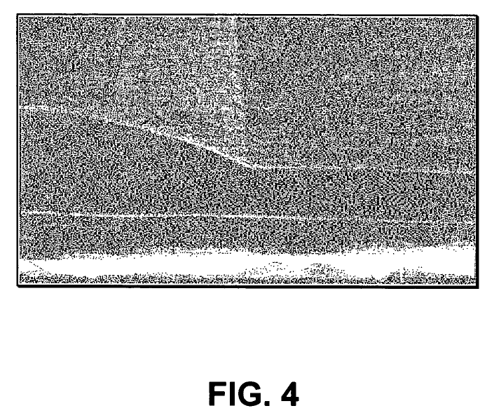

As described above and shown in FIG. 3B, control of a patterned resist reflow will form an angled sidewall 318 in a photoresist opening 317, that may be subsequently transferred during an etch process to produce a similarly sloped sidewall opening in the dielectric material 312 covering the bond pad 310. A patterned resist sidewall angle in the range of 30 to 60 degrees may be used to approximately transfer a similar slope to an etched dielectric opening. After the reflow process is completed, the resist profile opening was examined with an Electron Microscope. FIG. 4 illustrates the EM photograph showing the sloped sidewall of the resist opening after reflow.

After the sloped profile in a photoresist opening has been formed, a subsequent etch process will then remove the dielectric material and create an opening to the bond pad. The etch process exposes the bond pad and also approximately transfers the slope profile of the resist to the dielectric material formed over the bond pad. Similar to the slope profile of the resist layer, the opening in the dielectric material will be wider at its upper portion in comparison to its lower portion where the bond pad will be exposed.

In one embodiment, the etch process is tailored to balance the etch selectivity of the resist in comparison to the dielectric layer to transfer the photoresist sloped profile to the dielectric layer. The etch process should be selective as to etch the dielectric material below the patterned resist at a rate approximately equal to or faster in comparison to the rate of removing the resist material.

As illustrated in FIG. 3C, the etch process is partially complete. The resist 316, and underling layer of dielectric material 313, are selectively etched and the original sloped sidewall profile 318 of the patterned resist opening has been partially transferred to the dielectric layer 319.

In one embodiment, the etch process comprises the use of a generic plasma dielectric etch, including some optimization of the power and gas flows to vary the slope in the etched dielectric opening.

In FIG. 3D, the etch process has been completed, and the opening 323, in dielectric 322, now exposes the bond pad 310. The slope of the bond pad opening profile 321 is approximately equal to the original sloped sidewalls of the patterned resist opening. However, variances in the etch process may change the angle or slope profile of the dielectric material in comparison to the original sloped sidewalls of the patterned resist opening. Normally, further processing would be performed to remove any remaining resist material, etch residues, and contaminants.

An angle of the sloped dielectric sidewall is preferred at approximately 45 degrees, for example within the range of 40 to 50 degrees, to improve the uniformity of metal deposition. However, the profile angle may be controlled to maintain a higher angle, for example, to accommodate a higher density of bond pad openings. Also, the metalization critical angle varies with both the materials used and the chosen deposition process. The critical angle will be related to the sloped profile angle of the bond pad opening, but alternate embodiments exists outside of the dielectric slope angle range of 40 to 50 degrees. A shallow slope angle in the dielectric sidewall profile will successfully facilitate a subsequent etch metalization or conductor deposition, however, steeper angles in the photoresist sidewall may also improve a subsequent conductor deposition or metalization process.

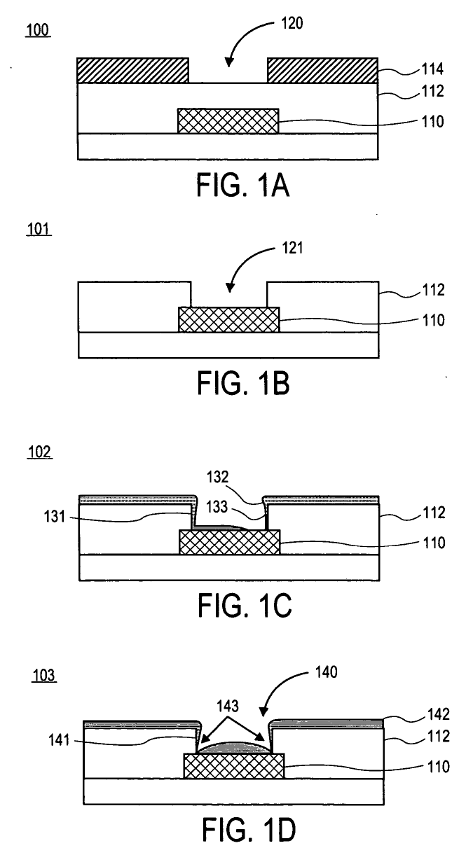

The sloped profile of the dielectric opening that exposes the bond pad is now ready for a subsequent metalization process. As shown in FIG. 3E, a metalization process will produce a more uniform metalization layer providing electrical contact with the bond pad. The metal conductors are formed for example, by depositing metals such as aluminum, copper, gold, silver, titanium, tungsten, and other equivalent materials or combinations of materials. Multiple metals depositions or multiple layers may also be formed over the bond pad opening. In FIG. 3E, the bond pad 310 is in contact with the metal deposition layer 342 which has an improved uniformity 340, due to the sloped profile angle of the dielectric material 322 over the bond pad. The sloped profile of the dielectric opening reduces or eliminates the shadowing or Damascene effect 350 of the metallization process in comparison to the prior art process as shown in FIGS. 1A-D.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art. In other instances well known semiconductor fabrication processes, techniques, materials, equipment, etc., have not been set forth in particular detail in order to not unnecessarily obscure the present invention.

1-15. (canceled)

16. A silicon substrate having a bond pad opening having been formed by a process comprising:
forming the bond pad over a silicon substrate;
forming a dielectric layer over the bond pad and silicon substrate;
forming a resist mask with at least one opening to expose the dielectric layer over the bond pad;
heating the resist mask with the at least one opening to form a sloped sidewall profile of the at least one opening of the resist mask; and
etching the resist mask and exposed dielectric layer to form at least one opening in the dielectric layer having a sloped sidewall profile.

17. The sloped sidewall profile of the opening in the dielectric layer of claim 16 wherein the sloped sidewall profile of the opening in the dielectric layer is wider at its upper end relative to its lower end.

18. The sloped sidewall profile of the opening in the dielectric layer of claim 16 wherein the sloped sidewall profile of the opening in the dielectric layer relative to the surface of the silicon substrate slopes at an angle of approximately 40 degrees to an angle of approximately 50 degrees.

19. The at least one opening in the dielectric layer of claim 16 wherein the at least one opening in the dielectric layer exposes the entire bondable surface of the bond pad.

20. The at least one opening in the dielectric layer of claim 16 wherein the at least one opening in the dielectric layer exposes less than the entire bondable surface of the bond pad.

21. The bond pad opening of claim 16 wherein the bond pad opening is used to interconnect an electronic switching transistor.
